(19) United States
(12) Patent Application Publication
(10) Pub. No.: US 2025/0372582 A1
(43) Pub. Date: Dec. 4, 2025

(54) SEMICONDUCTOR MODULE

(71) Applicant: FUJI ELECTRIC CO., LTD., Kawasaki-shi (JP)

(72) Inventor: Akira HIRAO, Matsumoto-city (JP)

(73) Assignee: FUJI ELECTRIC CO., LTD., Kawasaki-shi (JP)

(21) Appl. No.: 19/091,551

(22) Filed: Mar. 26, 2025

(30) Foreign Application Priority Data
May 28, 2024 (JP) 2024-086478

(51) Int. Cl. H01L 25/07; H01L 23/00; H05K 1/11; H05K 1/18

(52) U.S. Cl. CPC H01L 25/072; H01L 24/40; H01L 24/48; H05K 1/116; H05K 1/181; H01L 24/32; H01L 2224/32235; H01L 2224/40227; H01L 2224/48227; H01L 2924/13091; H05K 2201/09563; H05K 2201/10166

(57) ABSTRACT

A semiconductor module, including: an insulating substrate; a semiconductor chip; and a wiring substrate. The wiring substrate includes: an insulating layer; a plurality of wiring layers formed in the insulating layer, the plurality of wiring layers including a lowermost wiring layer provided at a lowermost level of the wiring substrate and bonded to a top surface of the insulating substrate, and an uppermost wiring layer provided at an uppermost level of the wiring substrate, the uppermost wiring layer being a semiconductor chip mounting wiring layer to which the semiconductor chip is bonded; and a metal inlay embedded in the wiring substrate between the semiconductor chip and the insulting substrate, the metal inlay being electrically connected to the semiconductor chip.

### CROSS-REFERENCE TO RELATED APPLICATION

This application is based upon and claims the benefit of priority of the prior Japanese Patent Application No. 2024-086478, filed on May 28, 2024, the entire contents of which are incorporated herein by reference.

### BACKGROUND OF THE INVENTION

### 1. Field of the Invention

The embodiment discussed herein relates to a semiconductor module.

### 2. Background of the Related Art

In a semiconductor module, electronic components are mounted on a printed circuit board having multiple laminated conductor layers (see, for example, Japanese Laid-open Patent Publication No. 2021-082652). A multi-layer wiring structure is disposed on a glass epoxy substrate, and electrodes are provided on an insulating layer, which is a surface layer of the multi-layer wiring structure (see, for example, Japanese Laid-open Patent Publication No. 2020-043249). Printed wirings that form high-frequency circuits are provided on the front surface, back surface, inside, and the like of a printed circuit board, and a copper inlay is placed in an opening of the printed circuit board (see, for example, Japanese Laid-open Patent Publication No. 2020-191316).

A copper inlay is fitted in the thickness direction of a substrate having an inner layer sandwiched between a first front surface and a second front surface (see, for example, Japanese Laid-open Patent Publication No. 2017-103371). A copper inlay is provided in a printed circuit board under a semiconductor chip, and an insulating sheet is laid between the printed circuit board and a heatsink (see, for example, Japanese Laid-open Patent Publication No. 2019-009153).

### SUMMARY OF THE INVENTION

According to an aspect, there is provided a semiconductor module including an insulating substrate; a semiconductor chip; and a wiring substrate including: an insulating layer; a plurality of wiring layers formed in the insulating layer, the plurality of wiring layers including: a lowermost wiring layer provided at a lowermost level of the wiring substrate and bonded to a top surface of the insulating substrate, and an uppermost wiring layer provided at an uppermost level of the wiring substrate, a portion of the uppermost wiring layer being a semiconductor chip mounting wiring layer to which the semiconductor chip is bonded; and a metal inlay embedded in the wiring substrate between the semiconductor chip and the insulting substrate, the metal inlay being electrically connected to the semiconductor chip.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor module;

FIG. 2 is a cross-sectional view of the semiconductor module;

FIG. 3 illustrates an example of a circuit configuration of semiconductor chip;

FIG. 4 illustrates a first mounting example of a snubber circuit;

FIG. 5 illustrates a second mounting example of the snubber circuit;

FIG. 6 illustrates an example of a cross-sectional view of a semiconductor module according to a first reference example;

FIG. 7 illustrates an example of a plan view of a semiconductor module according to a second reference example;

FIG. 8 illustrates an example of a cross-sectional view of the semiconductor module according to the second reference example;

FIG. 9 is a plan view of a semiconductor module according to a first modification;

FIG. 10 is a cross-sectional view of the semiconductor module according to the first modification;

FIG. 11 is a plan view of a semiconductor module according to a second modification;

FIG. 12 is a cross-sectional view of the semiconductor module according to the second modification; and

FIG. 13 is a cross-sectional view of a semiconductor module according to a third modification.

### DETAILED DESCRIPTION OF THE INVENTION

An embodiment will be described below with reference to the accompanying drawings. In the specification and the drawings, like reference numerals refer to components having substantially the same functions to avoid repetitive description. In the following description, the terms “top surface” and “front surface” refer to surfaces facing upward when viewed from the paper. Similarly, the terms “upper” and “upper side” refer to directions facing upward when viewed from the paper. On the other hand, the terms “bottom surface” and “back surface” refer to surfaces facing downward when viewed from the paper. Similarly, the terms “lower” and “lower side” refer to directions facing downward when viewed from the paper. These terms have the same orientational relationships in all drawings. The terms “top surface”, “front surface”, “upper”, “upper side”, “bottom surface”, “back surface”, “lower”, and “lower side” are simply expedient expressions used to specify relative positional relationships, and are not intended to limit the technical ideas of the embodiment described herein.

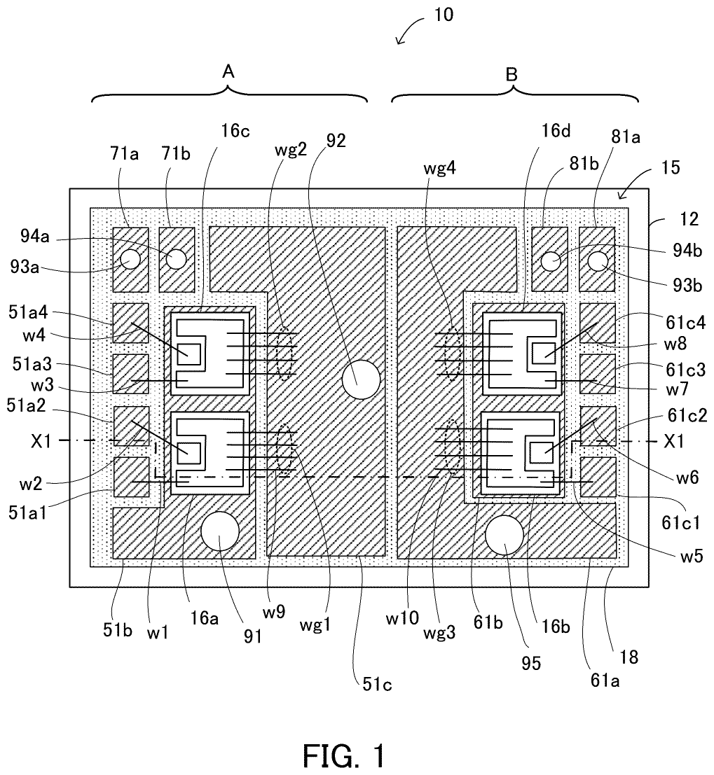

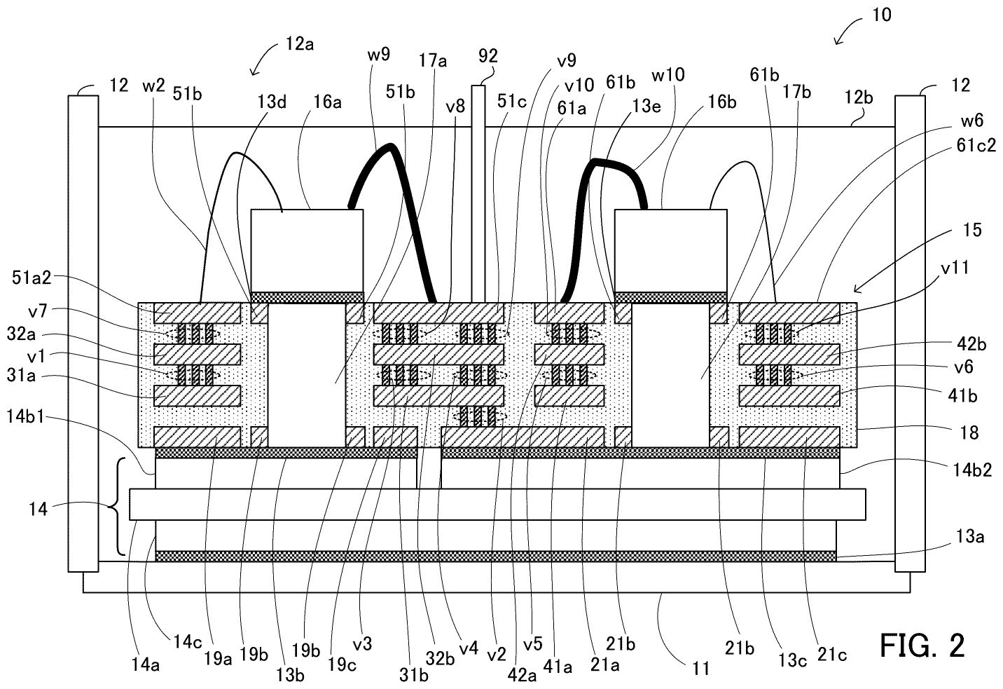

Semiconductor modules are described with reference to FIGS. 1 to 5. FIG. 1 is a plan view of a semiconductor module. FIG. 2 is a cross-sectional view of the semiconductor module. The cross-sectional view of FIG. 2 is taken along a dash-dotted line X1-X1 in FIG. 1. Note that FIG. 1 omits a sealing member.

A semiconductor module 10 configures a half-bridge circuit including an upper arm portion A and a lower arm portion B. The upper arm portion A of the semiconductor module 10 includes semiconductor chips 16a and 16c, and also includes a P terminal 91, an output terminal 92 (external output terminal), a gate terminal 93a, and an auxiliary source terminal 94a as external connection terminals. The lower arm portion B of the semiconductor module 10 includes semiconductor chips 16b and 16d, and also includes an N terminal 95, a gate terminal 93b, and an auxiliary source terminal 94b as external connection terminals.

The semiconductor chips 16a, 16b, 16c, and 16d may be made of silicon carbide as a main component. Such semiconductor chips are, for example, power metal-oxide-semiconductor field-effect transistors (power MOSFETs). In this case, the semiconductor chips 16a, 16b, 16c, and 16d each have, on the back surface, a drain electrode (first electrode) as an input electrode and, on the front surface, a gate electrode as a control electrode and a source electrode (second electrode) as an output electrode.

Instead, the semiconductor chips 16a, 16b, 16c, and 16d may be made of silicon as a main component. Such semiconductor chips may each include a reverse-conducting insulated gate bipolar transistor (RC-IGBT) having integrated functions of both an insulated gate bipolar transistor (IGBT) and free wheeling diode (FWD). These semiconductor chips each have, on the back surface, a collector electrode as an input electrode and, on the front surface, a gate electrode as a control electrode and an emitter electrode as an output electrode. Note that a case described in this embodiment as an example is that the semiconductor chips 16a, 16b, 16c, and 16d are power MOSFETs.

The thickness of each of the semiconductor chips 16a, 16b, 16c, and 16d is, for example, 80 μm or more and 500 μm or less, with an average thickness of about 200 μm. Each of the semiconductor chips 16a, 16b, 16c, and 16d is bonded to a predetermined wiring layer of a printed circuit board 15 via a bonding member. The bonding members may be solder or sintered metal compacts. The following is described assuming that solder is used for the bonding members.

The semiconductor module 10 includes a heat dissipation plate (base) 11 disposed on the back surface and a case 12 disposed on the heat dissipation plate 11 to cover the side surfaces. In addition, the semiconductor module 10 houses components in a housing space 12a surrounded by the heat dissipation plate 11 and the case 12. The components in the housing space 12a are sealed with a sealing member 12b. The sealing member 12b is a resin or gel, and, for example, a silicone gel or a resin with good conformability may be used.

The case 12 is molded using a thermoplastic resin. Examples of the resin include: a polyphenylene sulfide resin; a polybutylene terephthalate resin; a polybutylene succinate resin; a polyamide resin; and an acrylonitrile butadiene styrene resin.

The components provided in the housing space 12a include: an insulating substrate 14; the printed circuit board 15 (wiring substrate) disposed on the insulating substrate 14; the semiconductor chips 16a, 16b, 16c, and 16d; wires w1 to w10 and wire groups wg1 to wg4 connecting the semiconductor chips 16a, 16b, 16c, and 16d; and metal inlays 17a and 17b embedded in the printed circuit board 15.

The heat dissipation plate 11 is a plate-shaped member having a substantially rectangular shape in plan view. The outer shape of the heat dissipation plate 11 may be slightly smaller than that of the case 12. The corners of the heat dissipation plate 11 may be R- or C-chamfered. The heat dissipation plate 11 is made of a metal having excellent heat dissipation properties. Such a metal is, for example, copper, aluminum, silicon carbide, or an alloy containing at least one of these. Plating may be applied to the surface of the heat dissipation plate 11 to provide improved corrosion resistance. In this case, a material used for plating is, for example, nickel, a nickel-phosphorus alloy, or a nickel-boron alloy.

The insulating substrate 14 is bonded to the front surface of the heat dissipation plate 11 via solder 13a. The insulating substrate 14 includes an insulating plate 14a, metal plates 14b1 and 14b2 formed on the front surface of the insulating plate 14a, and a metal plate 14c formed on the back surface of the insulating plate 14a.

The insulating plate 14a has a rectangular shape in plan view. The corners of the insulating plate 14a may be R- or C-chamfered. The insulating plate 14a is made of ceramic with excellent thermal conductivity. The ceramic here is made of a material containing, for example, aluminum oxide, silicon nitride, or aluminum nitride as a main component.

The metal plates 14b1 and 14b2 are made of a metal having excellent electrical conductivity. Such a metal is, for example, copper, aluminum, or an alloy containing at least one of these. The metal plate 14c is made of a metal having excellent thermal conductivity as a main component. Such a metal is, for example, copper, aluminum, or an alloy containing at least one of these. Plating may be applied to coat the surfaces of the metal plates 14b1, 14b2, and 14c in order to provide improved corrosion resistance. In this case, a material used for plating is, for example, nickel, a nickel-phosphorus alloy, or a nickel-boron alloy.

On the other hand, the printed circuit board 15 having a multi-layer structure (three or more layers) formed by laminating an insulating layer 18 and multiple wiring layers is disposed on the top surface of the insulating substrate 14. The semiconductor chips 16a, 16b, 16c, and 16d are disposed on the top surface of the printed circuit board 15, and the metal inlays 17a and 17b (metal blocks) and the like are embedded vertically in the printed circuit board 15, between the semiconductor chips 16a, 16b, 16c, and 16d and the insulating substrate 14 in order to provide electrical connection and heat transport.

Note that FIG. 2 depicts a case in which the metal inlay 17a is embedded in the printed circuit board 15, between the semiconductor chip 16a and the insulating substrate 14, and the metal inlay 17b is embedded in the printed circuit board 15, between the semiconductor chip 16b and the insulating substrate 14.

An insulating resin may be used for the insulating layer 18 of the printed circuit board 15. The insulating resin may be, for example, a phenol resin; an epoxy resin; a polyimide resin; or a glass epoxy resin. Each wiring layer of the printed circuit board 15 is formed of a metal having excellent electrical conductivity. Such a metal is, for example, copper, aluminum, or an alloy containing at least one of these. Plating may be applied to coat the surfaces of the wiring layers in order to provide improved corrosion resistance. In this case, a material used for plating is, for example, aluminum, nickel, titanium, chromium, molybdenum, tantalum, niobium, tungsten, vanadium, bismuth, zirconium, hafnium, gold, silver, platinum, palladium, or an alloy containing at least one of these. Note that the number, installation sites, and shapes of the wiring layers may be appropriately selected by design.

The metal inlays 17a and 17b are made of a metal having excellent electrical conductivity. Such a metal is, for example, copper, aluminum, or an alloy containing at least one of these. The metal inlays 17a and 17b are pressed into holes (not illustrated) provided in the printed circuit board 15 to be thus embedded in the printed circuit board 15. The width of the metal inlays 17a and 17b is preferably equal to or greater than that of the semiconductor chips 16a and 16b. This allows the heat of the semiconductor chips 16a and 16b to be efficiently conducted to the insulating substrate 14.

Layers at the lowermost level of the printed circuit board 15 are connected to the insulating substrate 14. At the lowermost level of the printed circuit board 15, wiring layers 19a, 19b, 19c, 21a, 21b, and 21c (lowermost wiring layer) are formed. The wiring layers 19a, 19b, and 19c are bonded to the metal plate 14b1 via solder 13b. Note that the bottom surface of the metal inlay 17a is bonded to the metal plate 14b1 via the solder 13b, and further, the side surface of the metal inlay 17a on the insulating substrate 14 side is electrically connected to the wiring layer 19b.

The wiring layers 21a, 21b, and 21c are bonded to the metal plate 14b2 via solder 13c. The back surfaces of the wiring layers 19a, 19b, 19c, 21a, 21b, and 21c are bonded to the top surface of the insulating substrate 14. Note that the back surface of the metal inlay 17b is bonded to the metal plate 14b2 via the solder 13c, and further, the lower side surface of the metal inlay 17b is electrically connected to the wiring layer 21b.

For example, main circuits through which main currents flow are formed in the inner layers of the printed circuit board 15. The number of inner layers varies depending on the complexity of the wiring layers and the magnitude of the main currents. Field vias (conductive vias) are used to connect the individual inner wiring layers.

In the inner layers of the printed circuit board 15, wiring layers 31a, 31b, 32a, 32b, 41a, 41b, 42a, and 42b (inner wiring layers) are formed. The wiring layers 31a is bonded to the wiring layer 32a through field vias v1 (first conductive vias). The wiring layer 31b is bonded to the wiring layer 21a (first lowermost wiring layer) through field vias v2 (third conductive vias), and bonded to the wiring layer 32b through field vias v3 and v4 (first conductive vias). Note that it is possible to reduce wiring inductance by arranging the wiring layers 31a, 31b, 32a, 32b, 41a, 41b, 42a, and 42b (inner wiring layers) so as to obtain mutual interaction.

The wiring layer 41a is bonded to the wiring layer 42a through field vias v5 (first conductive via). The wiring layer 41b is bonded to the wiring layer 42b via field vias v6 (first conductive via).

The uppermost level of the printed circuit board 15 includes layers serving as bonding areas for wires connecting semiconductor chips and wiring layers, and layers on which external connection terminals for connecting an external device to the semiconductor module 10 are disposed.

At the uppermost level of the printed circuit board 15, wiring layers 51a1, 51a2, 51a3, 51a4, 51b, 51c, 71a, and 71b (uppermost wiring layers) are formed on the upper arm portion A side. Also, wiring layers 61a, 61b, 61c1, 61c2, 61c3, 61c4, 81a, and 81b (uppermost wiring layers) are formed on the lower arm portion B side.

The semiconductor chips 16a and 16c are bonded to the wiring layer 51b (semiconductor chip mounting wiring layer), and the semiconductor chips 16b and 16d are bonded to the wiring layer 61b (semiconductor chip mounting wiring layer). FIG. 2 depicts that the drain electrode of the semiconductor chip 16a is bonded to the wiring layer 51b and the top surface of the metal inlay 17a via solder 13d. FIG. 2 also depicts that the drain electrode of the semiconductor chip 16b is bonded to the wiring layer 61b and the top surface of the metal inlay 17b via solder 13e. In addition, the side surface of the metal inlay 17a on the semiconductor chip 16a side is electrically connected to the wiring layer 51b, and the side surface of the metal inlay 17b on the semiconductor chip 16b side is electrically connected to the wiring layer 61b.

Note that lead-free solder is used for the solder 13a, 13b, 13c, 13d, and 13e. The lead-free solder contains, as a main component, at least one alloy selected from, for example, a tin-silver-copper alloy, a tin-zinc-bismuth alloy, a tin-copper alloy, and a tin-silver-indium-bismuth alloy. Instead of solder, sintered metal compacts may be used. The material of the sintered metal compacts is silver, gold, nickel, copper, or an alloy containing at least one of these.

The source electrode of the semiconductor chip 16a is bonded to the wiring layer 51a1 (second uppermost wiring layer) via the wire w1 (second wiring member: second wire connecting the source electrode and the wiring layer), and is further bonded to the wiring layer 51c (third uppermost wiring layer) via the wire group wg1 (third wiring member) made up of multiple wires including the wire w9. The gate electrode of the semiconductor chip 16a is bonded to the wiring layer 51a2 (first uppermost wiring layer) via the wire w2 (first wiring member: first wire connecting the gate electrode and the wiring layer).

The source electrode of the semiconductor chip 16c is bonded to the wiring layer 51a3 (second uppermost wiring layer) via the wire w3 (second wiring member), and is further bonded to the wiring layer 51c (third uppermost wiring layer) via the wire group wg2 (third wiring member) made up of multiple wires. The gate electrode of the semiconductor chip 16c is bonded to the wiring layer 51a4 (first uppermost wiring layer) via the wire w4 (first wiring member).

The source electrode of the semiconductor chip 16b is bonded to the wiring layer 61c1 (second uppermost wiring layer) via the wire w5 (second wiring member), and is further bonded to the wiring layer 61a (third uppermost wiring layer) via the wire group wg3 (third wiring member) made up of multiple wires including the wire w10. The gate electrode of the semiconductor chip 16b is bonded to the wiring layer 61c2 (first uppermost wiring layer) via the wire w6 (first wiring member).

The source electrode of the semiconductor chip 16d is bonded to the wiring layer 61c3 (second uppermost wiring layer) via the wire w7 (second wiring member), and is further bonded to the wiring layer 61a (third uppermost wiring layer) via the wire group wg4 (third wiring member) made up of multiple wires. The gate electrode of the semiconductor chip 16d is bonded to the wiring layer 61c4 (first uppermost wiring layer) via the wire w8 (first wiring member).

The aforementioned wires w1, w2, w3, w4, w5, w6, w7, w8, w9, and w10 and wire groups wg1, wg2, wg3, and wg4 are aluminum wires. Wire bonding is performed using ultrasonic waves or load.

The diameter of each of the wires w2, w4, w6, and w8 used for the gate electrodes of the semiconductor chips 16a, 16b, 16c, and 16d is, for example, 20 μm or more and 500 μm or less. The diameter of each of the wires w1, w3, w5, and w7 used for the source electrodes of the semiconductor chips 16a, 16b, 16c, and 16d and the diameter of each of the wires w9, w10 and so on making up of the wire groups wg1, wg2, wg3, and wg4 are, for example, 200 μm or more and 500 μm or less.

As for bonding the external connection terminals and the uppermost wiring layers, the P terminal 91, which serves as a positive terminal in the half-bridge circuit, is attached to the wiring layer 51b, and the N terminal 95, which serves as a negative terminal in the half-bridge circuit, is attached to the wiring layer 61a.

The gate terminal 93a is attached to the wiring layer 71a, and the auxiliary source terminal 94a is attached to the wiring layer 71b. The gate terminal 93b is attached to the wiring layer 81a, and the auxiliary source terminal 94b is attached to the wiring layer 81b.

On the other hand, as for bonding the uppermost wiring layers and the inner wiring layers, the wiring layer 51a2 is bonded to the wiring layer 32a through field vias v7 (second conductive vias). The wiring layer 51c is bonded to the wiring layer 32b through field vias v8 and v9 (second conductive vias). The wiring layer 61a is bonded to the wiring layer 42a through field vias v10 (second conductive vias). The wiring layer 61c2 is bonded to the wiring layer 42b through field vias v11 (second conductive vias).

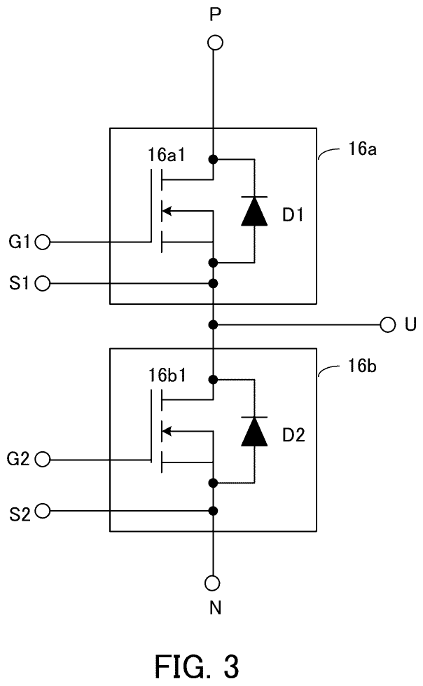

FIG. 3 illustrates an example of a circuit configuration of semiconductor chips, and depicts a configuration example of the semiconductor chip 16a of the upper arm portion A and the semiconductor chip 16b of the lower arm portion B. The switching element of the semiconductor chip 16a is made up of a MOSFET 16a1 and a diode D1 of the MOSFET 16a1. The switching element of the semiconductor chip 16b is made up of a MOSFET 16b1 and a diode D2 of the MOSFET 16b1.

The drain electrode of the MOSFET 16a1 is connected to a P terminal and the cathode of the diode D1. The gate electrode of the MOSFET 16a1 is connected to a gate terminal G1. The source electrode of the MOSFET 16a1 is connected to the anode of the diode D1, an auxiliary source terminal S1, an output terminal U, the drain electrode of MOSFET 16b1, and the cathode of the diode D2. The gate electrode of the MOSFET 16b1 is connected to a gate terminal G2. The source electrode of the MOSFET 16b1 is connected to an auxiliary source terminal S2 and an N terminal.

Note that the gate terminal G1 corresponds to the gate terminal 93a, and the gate terminal G2 corresponds to the gate terminal 93b. The auxiliary source terminal S1 corresponds to the auxiliary source terminal 94a, and the auxiliary source terminal S2 corresponds to the auxiliary source terminal 94b. The P terminal corresponds to the P terminal 91, the N terminal corresponds to the N terminal 95, and the output terminal U corresponds to the output terminal 92.

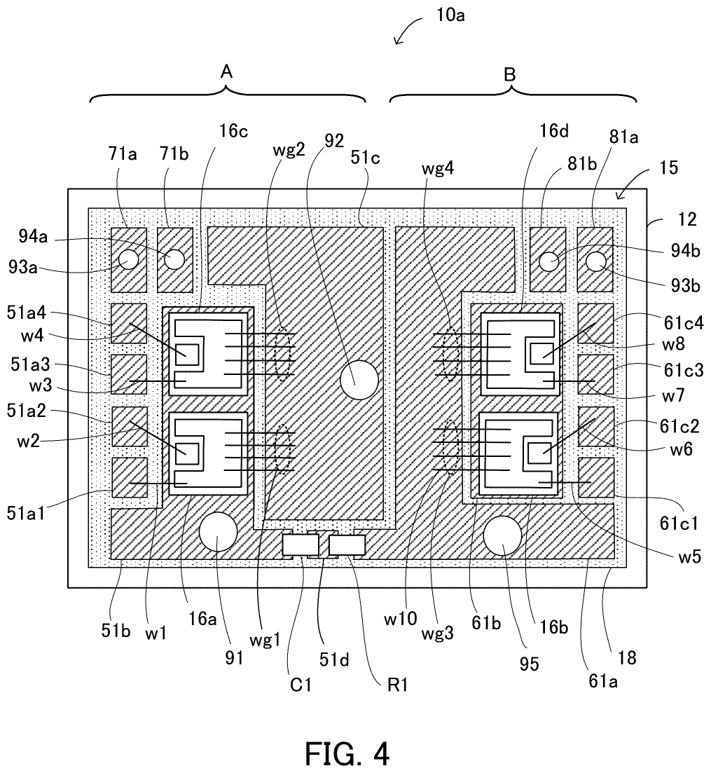

FIG. 4 illustrates a first mounting example of a snubber circuit, in which the snubber circuit formed by combining a capacitor and a resistor or the like is mounted between the P terminal 91 and the N terminal 95 at the uppermost level of a semiconductor module 10a.

The uppermost level of the printed circuit board 15 includes the wiring layers 51b and 61a and a wiring layer 51d as circuit element mounting uppermost wiring layers on which circuit elements, such as a capacitor and a resistor, are mounted. A first end of a capacitor C1 is bonded to the wiring layer 51b, and a second end of the capacitor C1 is bonded to the wiring layer 51d. A first end of a resistor R1 is bonded to the wiring layer 61a, and a second end of the resistor R1 is bonded to the wiring layer 51d.

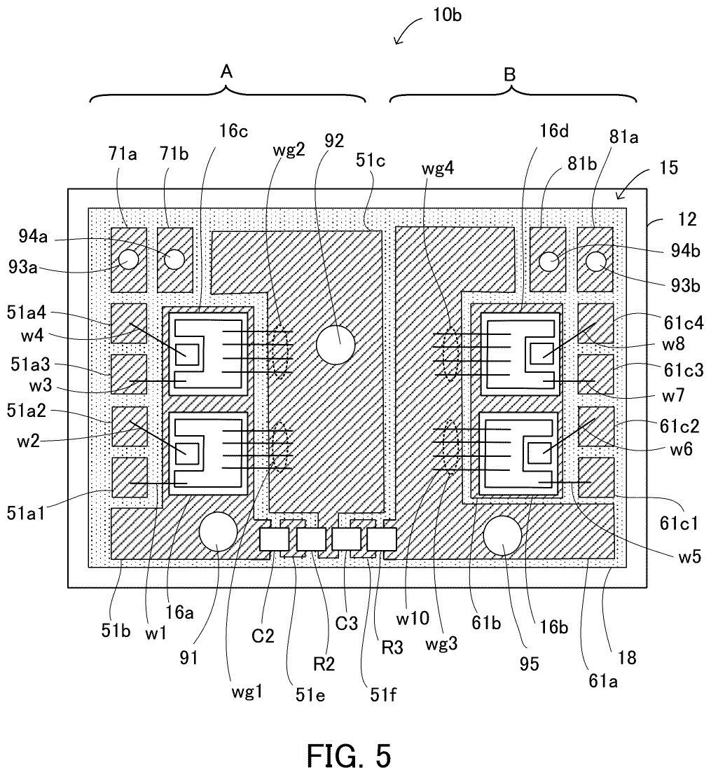

FIG. 5 illustrates a second mounting example of a snubber circuit, in which the snubber circuit formed by combining capacitors and resistors or the like is mounted between the upper arm portion A and the lower arm portion B at the uppermost level of a semiconductor module 10b.

The uppermost level of the printed circuit board 15 includes the wiring layers 51b, 51c, and 61a and wiring layers 51e and 51f as circuit element mounting uppermost wiring layers on which circuit elements, such as capacitors and resistors, are mounted. A first end of a capacitor C2 is bonded to the wiring layer 51b, and a second end of the capacitor C2 is bonded to the wiring layer 51e. A first end of a resistor R2 is bonded to the wiring layer 51e, and a second end of the resistor R2 is bonded to the wiring layer 51c. A first end of a capacitor C3 is bonded to the wiring layer 51c, and a second end of the capacitor C3 is bonded to the wiring layer 51f. A first end of a resistor R3 is bonded to the wiring layer 51f, and a second end of the resistor R3 is bonded to the wiring layer 61a.

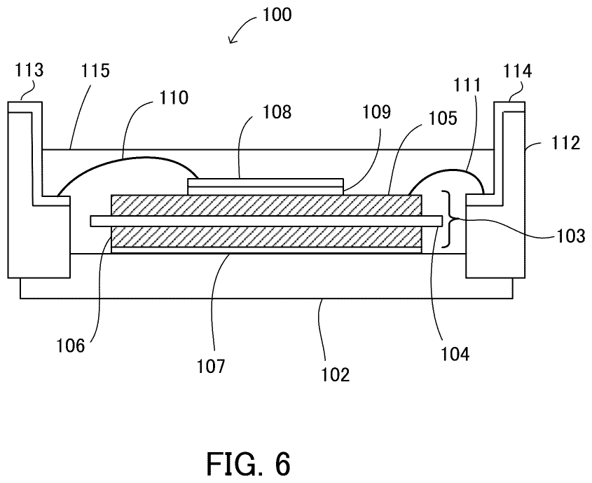

Next described are semiconductor modules according to reference examples. FIG. 6 illustrates an example of a cross-sectional view of a semiconductor module according to a first reference example. A semiconductor module 100 according to the first reference example includes a power semiconductor chip and an insulating substrate, and has a wiring structure using wires.

In the semiconductor module 100, an insulating substrate 103 is mounted on the top surface of a copper base (heat dissipation plate) 102. The insulating substrate 103 includes an insulating layer 104 and copper plates 105 and 106. The copper plate 106 of the insulating substrate 103 is bonded onto the copper base 102 via solder 107. A power semiconductor chip 108 is bonded onto the copper plate 105 of the insulating substrate 103 via solder 109.

Wires 110 and 111 are bonding wires made of aluminum. The wire 110 bonds an electrode on the top surface of the power semiconductor chip 108 to an external terminal 113 provided on a case 112. The wire 111 bonds the copper plate 105 to an external terminal 114 provided on the case 112. The bonding with the wires 110 and 111 is performed by wire bonding using ultrasonic waves and a load.

The insulating substrate 103 with the power semiconductor chip 108 bonded thereto is housed in the case 112, and a space surrounded by the case 112 and the copper base 102 is filled with a sealing member 115 and thus sealed.

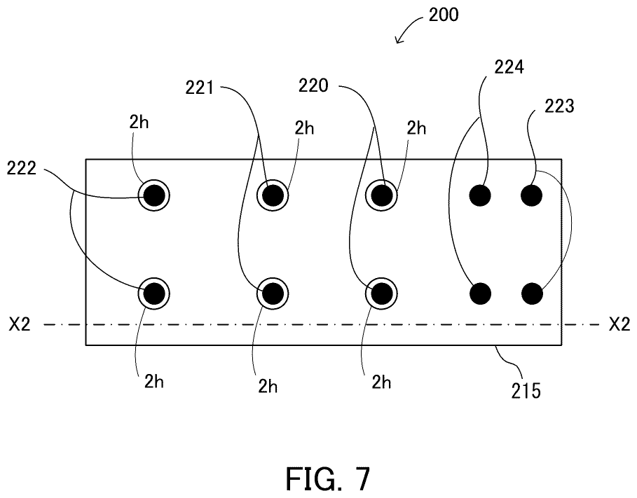

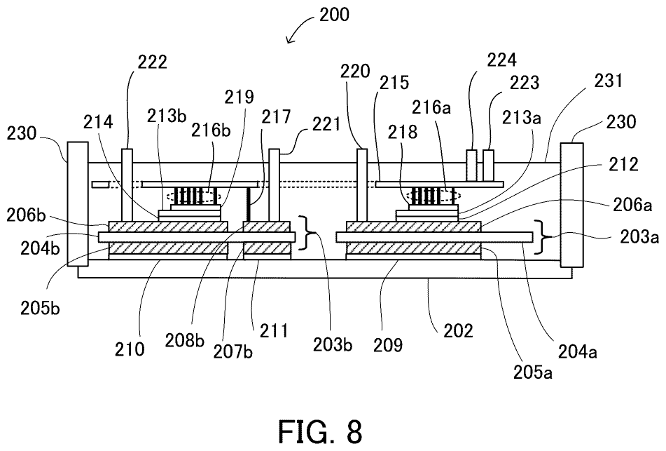

FIG. 7 illustrates an example of a plan view of a semiconductor module according to a second reference example. FIG. 8 illustrates an example of a cross-sectional view of the semiconductor module according to the second reference example. The cross-sectional view of FIG. 8 is taken along a dash-dotted line X2-X2 in FIG. 7.

A semiconductor module 200 of the second reference example includes two circuit units each including a power semiconductor chip and an insulating substrate, and has a wiring structure using a printed circuit board and conductive pin terminals. Insulating substrates 203a and 203b are mounted on the top surface of a copper base 202. The insulating substrate 203a has an insulating layer 204a and copper plates 205a and 206a, and the insulating substrate 203b has an insulating layer 204b and copper plates 205b, 206b, 207b, and 208b.

The copper plate 205a of the insulating substrate 203a is bonded to the copper base 202 via solder 209. The copper plate 205b of the insulating substrate 203b is bonded to the copper base 202 via solder 210, and the copper plate 207b of the insulating substrate 203b is bonded to the copper base 202 via solder 211.

A power semiconductor chip 213a is bonded onto the copper plate 206a of the insulating substrate 203a via solder 212, and a power semiconductor chip 213b is bonded onto the copper plate 206b of the insulating substrate 203b via solder 214.

A printed circuit board 215 includes an insulating plate and wiring layers formed on the front and back surfaces of the insulating plate, and also has multiple holes 2h penetrating from the front surface to the back surface, formed at positions corresponding to external terminals 220, 221, and 222.

Furthermore, post electrodes 216a, 216b, and 217 are provided as pin terminals on the wiring layer of the back surface of the printed circuit board 215. The post electrodes 216a, 216b, and 217 are bonded to the insulating substrate side, which provides support to the printed circuit board 215. The printed circuit board 215 provides an electrical connection between the two circuit units.

The post electrodes 216a are bonded to an electrode on the front surface of the power semiconductor chip 213a via solder 218, and the post electrodes 216b are bonded to an electrode on the front surface of the power semiconductor chip 213b via solder 219. The post electrode 217 is directly bonded to the copper plate 208b.

The external terminal 220 is a P terminal for supplying current to the back surface of the power semiconductor chip 213a. A first end of the external terminal 220 is directly bonded to the copper plate 206a and a second end thereof passes through the hole 2h of the printed circuit board 215 to protrude to the outside.

The external terminal 221 is an N terminal for allowing current from the front surface of the power semiconductor chip 213b to flow to the outside. A first end of the external terminal 221 is directly bonded to the copper plate 208b and a second end thereof passes through the hole 2h of the printed circuit board 215 to protrude to the outside.

The external terminal 222 is an output terminal for passing an output current from an intermediate node between a low potential side wiring of the power semiconductor chip 213a and a high potential side wiring of the power semiconductor chip 213b. A first end of the external terminal 222 is directly bonded to the copper plate 206b and a second end thereof passes through the hole 2h of the printed circuit board 215 to protrude to the outside.

An external terminal 223 is an external terminal for a gate signal that controls ON-OFF switching of the power semiconductor chips 213a and 213b, and is bonded to a wiring layer on the front surface of the printed circuit board 215. An external terminal 224 is an external voltage sense terminal that detects the low-potential-side voltage of the power semiconductor chips 213a and 213b, and is bonded to a wiring layer on the front surface of the printed circuit board 215.

The insulating substrates 203a and 203b, to which the power semiconductor chips 213a and 213b are bonded, are housed in a case 230, and the space surrounded by the case 230 and the copper base 202 is filled and sealed with a sealing member 231 up to a predetermined height from the front surface of the printed circuit board 215.

Note here that, in the semiconductor module 100 of the first reference example, wires are used for the wiring structure. However, in the case of the wiring structure using wires, bonding areas need to be provided on the insulating substrate 103 in order to form a circuit, which makes it difficult to miniaturize the semiconductor module 100.

On the other hand, in the semiconductor module 200 of the second reference example, a printed circuit board and pin terminals are used for the wiring structure. Unlike the wiring structure using wires, there is no need to provide bonding areas in the case of the wiring structure using a printed circuit board and pin terminals. As a result, the wiring structure using a printed circuit board and pin terminals facilitates miniaturization of the semiconductor module 200.

However, the printed circuit board placed over the power semiconductor chips hides circuit components, such as the power semiconductor chips, which makes alignment of the circuit components during component mounting and inspection of circuit joints difficult. This therefore leads to decreased reliability of the inspection.

On the other hand, the semiconductor module 10 of the embodiment described above has a multi-layer printed circuit board bonded to the top surface of the insulating substrate, and the multi-layer printed circuit board has metal inlays provided directly below semiconductor chips.

This allows for provision of layers serving as bonding areas at the uppermost level of the printed circuit board 15 as well as formation of main circuits and the like using the multiple wiring layers of the printed circuit board 15. As a result, it is possible to achieve high density mounting and module miniaturization compared to the semiconductor module 100 of the first reference example having a wiring structure using wires. Furthermore, the semiconductor module 10 of the embodiment described above has reduced problems in alignment of circuit components during component mounting and inspection of circuit joints compared to the semiconductor module 200 of the second reference example having a wiring structure using a printed circuit board and pin terminals. Thus, it is possible to improve the reliability of the inspection.

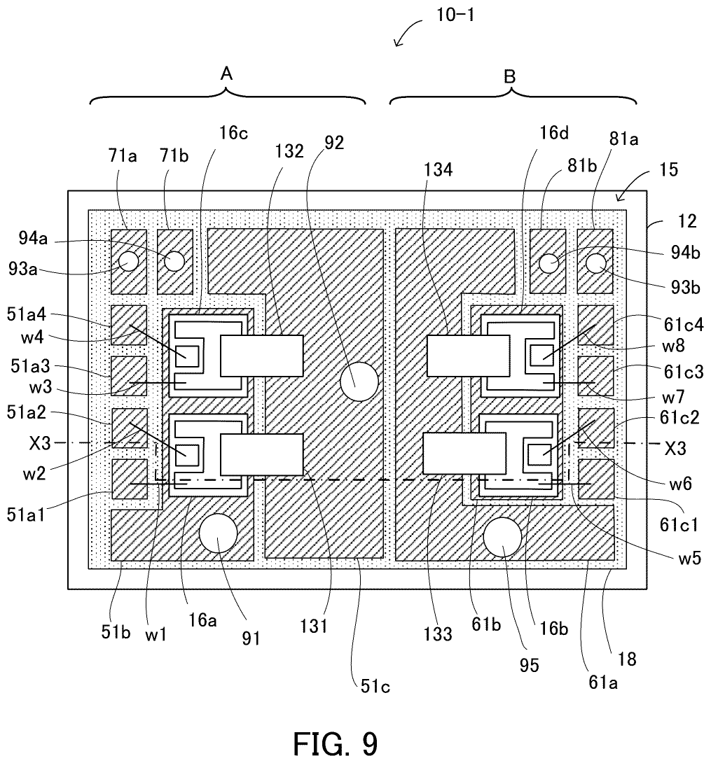

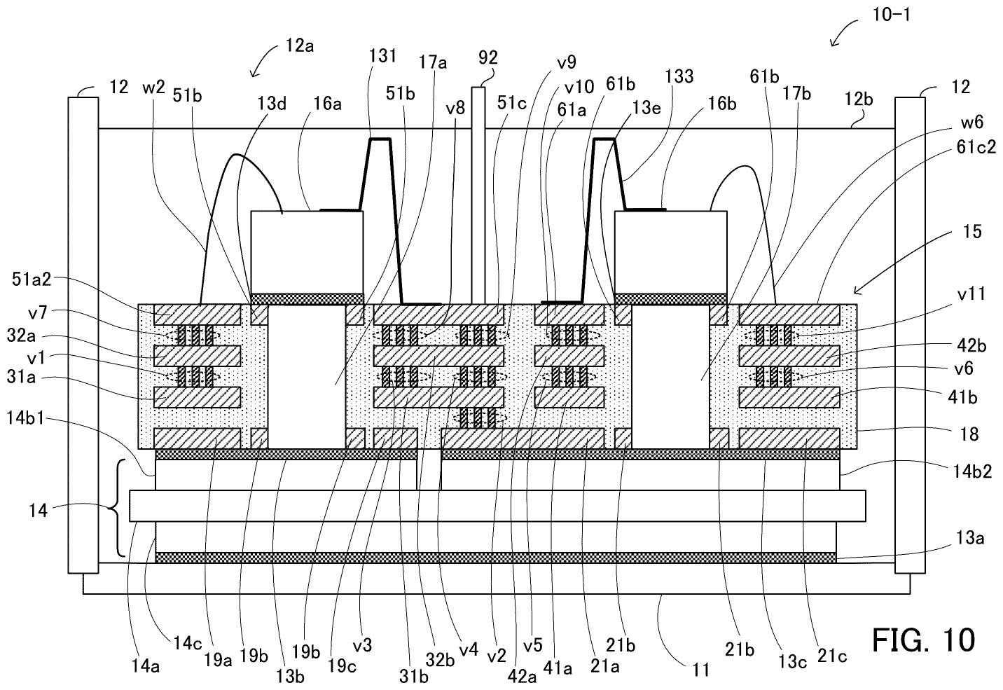

Next described are modifications of the semiconductor module 10. FIG. 9 is a plan view of a semiconductor module according to a first modification. FIG. 10 is a cross-sectional view of the semiconductor module of the first modification. The cross-sectional view of FIG. 10 is taken along a dash-dotted line X3-X3 in FIG. 9. Note that FIG. 9 omits a sealing member.

A semiconductor module 10-1 of the first modification uses lead frames 131, 132, 133, and 134 instead of the wire groups wg1, wg2, wg3, and wg4 depicted in FIG. 1. The remaining configuration is the same as that of the semiconductor module 10.

The source electrode of the semiconductor chip 16a is bonded to the wiring layer 51c via the lead frame 131, and is bonded to the wiring layer 51a1 via the wire w1. The source electrode of the semiconductor chip 16b is bonded to the wiring layer 61a via the lead frame 133, and is bonded to the wiring layer 61c1 via the wire w5.

The source electrode of the semiconductor chip 16c is bonded to the wiring layer 51c via the lead frame 132, and is bonded to the wiring layer 51a3 via the wire w3. The source electrode of the semiconductor chip 16d is bonded to the wiring layer 61a via the lead frame 134, and is bonded to the wiring layer 61c3 via the wire w7.

The lead frames 131, 132, 133, and 134 may be made of a metal material, such as copper, and may be connected to the source electrodes of the semiconductor chips and the wiring layers via solder or sintered compacts. Such a wiring structure with lead frames allows larger currents to flow than when aluminum wires are used, and further improves the reliability of wiring joints.

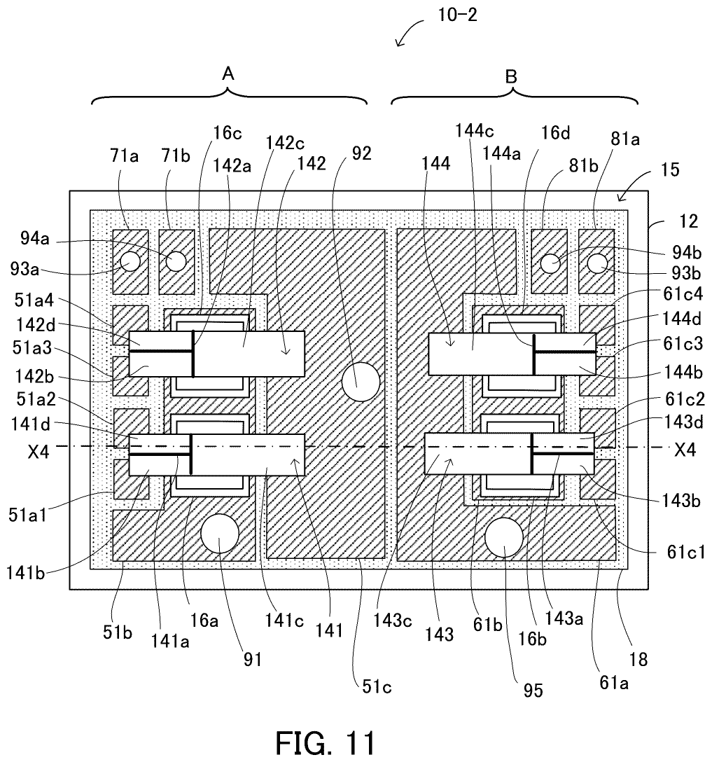

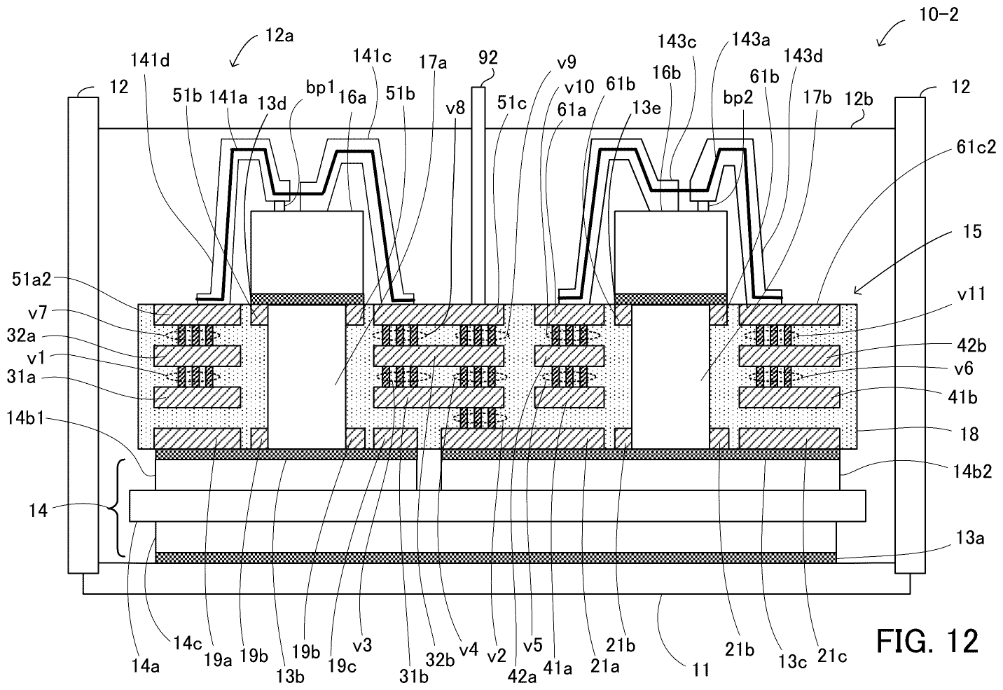

FIG. 11 is a plan view of a semiconductor module of a second modification. FIG. 12 is a cross-sectional view of the semiconductor module of the second modification. The cross-sectional view of FIG. 12 is taken along a dash-dotted line X4-X4 in FIG. 11. Note that FIG. 11 omits a sealing member.

A semiconductor module 10-2 of the second modification uses flexible substrates 141, 142, 143, and 144 instead of the wires w1, w2, w3, w4, w5, w6, w7, w8, w9, and wl0 and the wire groups wg1, wg2, wg3, and wg4 depicted in FIG. 1. The remaining configuration is the same as that of the semiconductor module 10.

The flexible substrate 141 includes an insulating film 141a and conductive patterns 141b, 141c, and 141d. The insulating film 141a insulates the conductive patterns 141b, 141c, and 141d from each other. The area of the conductive pattern 141c is larger than the area of the conductive pattern 141b and the conductive pattern 141d.

The flexible substrate 142 includes an insulating film 142a and conductive patterns 142b, 142c, and 142d. The insulating film 142a insulates the conductive patterns 142b, 142c, and 142d from each other. The area of the conductive pattern 142c is larger than the area of the conductive patterns 142b and 142d.

The flexible substrate 143 includes an insulating film 143a and conductive patterns 143b, 143c, and 143d. The insulating film 143a insulates the conductive patterns 143b, 143c, and 143d from each other. The area of the conductive pattern 143c is larger than the area of the conductive patterns 143b and 143d.

The flexible substrate 144 includes an insulating film 144a and conductive patterns 144b, 144c, and 144d. The insulating film 144a insulates the conductive patterns 144b, 144c, and 144d from each other. The area of the conductive pattern 144c is larger than the area of the conductive patterns 144b and 144d. Note that the conductive patterns above are formed of, for example, copper foil.

In bonding of the flexible substrate 141, the source electrode of the semiconductor chip 16a is bonded to the wiring layer 51a1 via the conductive pattern 141b (second conductive pattern), and is further bonded to the wiring layer 51c via the conductive pattern 141c (third conductive pattern). The gate electrode of the semiconductor chip 16a is bonded to the wiring layer 51a2 via a conductive bump and the conductive pattern 141d (first conductive pattern). FIG. 12 depicts that the gate electrode of the semiconductor chip 16a is bonded to the wiring layer 51a2 via a conductive bump bp1 and the conductive pattern 141d.

In bonding of the flexible substrate 142, the source electrode of the semiconductor chip 16c is bonded to the wiring layer 51a3 via the conductive pattern 142b (second conductive pattern), and is further bonded to the wiring layer 51c via the conductive pattern 142c (third conductive pattern). The gate electrode of the semiconductor chip 16c is bonded to the wiring layer 51a4 via a conductive bump and the conductive pattern 142d (first conductive pattern).

In bonding of the flexible substrate 143, the source electrode of the semiconductor chip 16b is bonded to the wiring layer 61c1 via the conductive pattern 143b (second conductive pattern), and is further bonded to the wiring layer 61a via the conductive pattern 143c (third conductive pattern). The gate electrode of the semiconductor chip 16b is bonded to the wiring layer 61c2 via a conductive bump and the conductive pattern 143d (first conductive pattern). FIG. 12 depicts that the gate electrode of the semiconductor chip 16b is bonded to the wiring layer 61c2 via a conductive bump bp2 and the conductive pattern 143d.

In bonding of the flexible substrate 144, the source electrode of the semiconductor chip 16d is bonded to the wiring layer 61c3 via the conductive pattern 144b (second conductive pattern), and is further bonded to the wiring layer 61a via the conductive pattern 144c (third conductive pattern). The gate electrode of the semiconductor chip 16d is bonded to the wiring layer 61c4 via a conductive bump and the conductive pattern 144d (first conductive pattern). Such a wiring structure with flexible substrates allows larger currents to flow than when aluminum wires are used, and further improves the reliability of wiring joints.

The bonding area of the gate electrode of each semiconductor chip is smaller than that of the conductive pattern of the corresponding flexible substrate. Therefore, the gate electrode of the semiconductor chip and the conductive pattern of the flexible substrate are bonded to each other via a conductive bump having an area that may be bonded to the gate electrode.

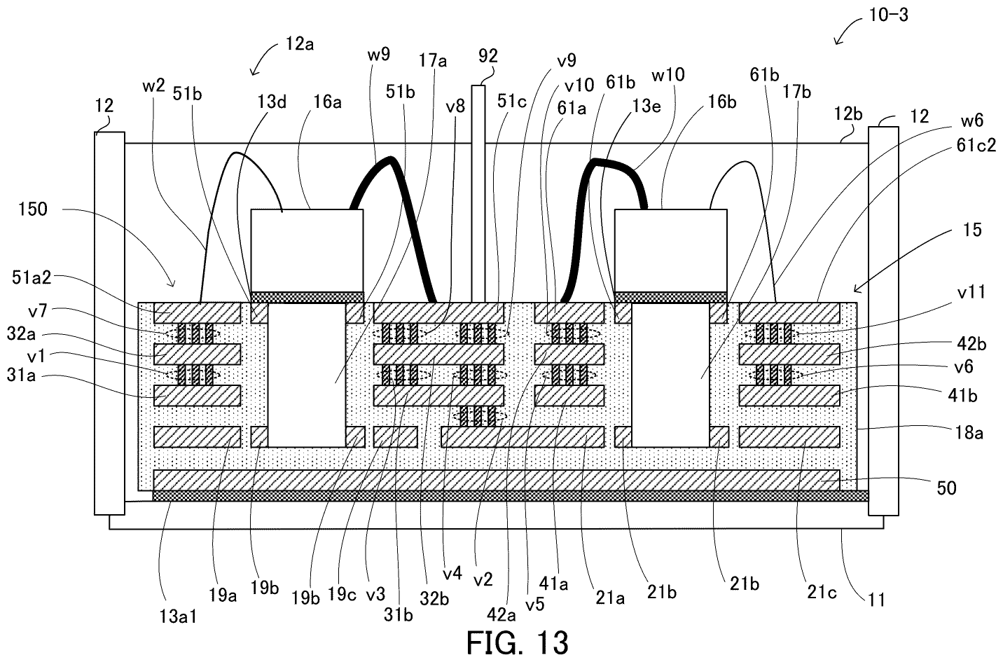

FIG. 13 is a cross-sectional view of a semiconductor module according to a third modification. A semiconductor module 10-3 according to the third modification has a configuration in which the above-described insulating substrate 14 and printed circuit board 15 are integrated using a resin insulating substrate 150. A wiring layer 50 is provided at the lowermost level of the resin insulating substrate 150, and the wiring layer 50 is bonded to the heat dissipation plate 11 via solder 13a1.

The resin insulating substrate 150 has the following structure. That is, a resin insulating layer 18a made of a resin based on epoxy or the like mixed with a thermally conductive filler, such as alumina, aluminum nitride, or boron nitride, is laminated with wiring layers of aluminum, copper, or the like and bonded to the heat dissipation plate 11, and semiconductor chips are bonded via solder or sintered compacts to the surfaces of the wiring layers, which have been etched into patterns.

By integrating the insulating substrate 14 and the printed circuit board 15 using the resin insulating substrate 150, the difference in the expansion coefficient between components is reduced, which thereby reduces thermal stress. This allows the resin insulating layer 18a to be made thinner and also makes it possible to reduce the number of bonding layers, thereby realizing a module with a heat dissipation structure that is highly reliable and has low thermal resistance.

As explained above, the semiconductor module 10 of the embodiment includes the insulating substrate 14; the semiconductor chips 16a to 16d; and the printed circuit board 15 (wiring substrate) that has multiple wiring layers and the insulating layer 18 provided between the multiple wiring layers. The multiple wiring layers include the lowermost wiring layers 19a, 19b, 19c, 21a, 21b, and 21c formed at the lowermost level and bonded to the top surface of the insulating substrate 14; and the uppermost wiring layers 51a1, 51a2, 51a3, 51a4, 51b, 51c, 51d, 51e, 51f, 61a, 61b, 61c1, 61c2, 61c3, 61c4, 71a, 71b, 81a, and 81b formed at the uppermost level and including the wiring layers 51b and 61b (semiconductor chip mounting wiring layers) to which the semiconductor chips 16a to 16d are bonded. In the printed circuit board 15 (wiring substrate), the metal inlays 17a and 17b electrically connected to the semiconductor chips 16a to 16d are embedded between the semiconductor chips 16a to 16d and the insulating substrate 14.

Herewith, by providing the printed circuit board 15 on the insulating substrate 14, it becomes possible to form multiple circuits below the bonding areas of the wires w1 to w10 and the wire groups wg1 to wg4 (topmost wiring layers 51a1, 51a2, 51a3, 51a4, 51b, 51c, 51d, 51e, 51f, 61a, 61b, 61c1, 61c2, 61c3, and 61c4), which makes it possible to reduce the size of the semiconductor module 10.

In addition, since the semiconductor chips 16a to 16d are not hidden by the printed circuit board 15 in plan view, it becomes easier to check their placement. This therefore reduces the difficulty of aligning the semiconductor chips 16a to 16d when disposing them. Furthermore, quality check becomes easier in conventional inspections. In addition, the printed circuit board 15 is bonded onto the insulating substrate 14, which allows the printed circuit board 15 to be cooled. The printed circuit board 15 is attached to the insulating substrate 14, and this structure provides more advantageous insulating and thermal properties than a structure where an insulating sheet is attached to the printed circuit board 15.

While, as described above, the embodiment has been exemplified, the configurations of individual portions illustrated in the embodiment may be replaced with others having the same functions. In addition, other constituent elements or processes may be added thereto. Furthermore, two or more compositions (features) of the embodiment may be combined together.

According to one aspect, it is possible to reduce the size of a module, and also improve ease of alignment when mounting components and the reliability of inspection of circuit joints.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
an insulating substrate;
a semiconductor chip; and
a wiring substrate including:
an insulating layer;
a plurality of wiring layers formed in the insulating layer, the plurality of wiring layers including:
a lowermost wiring layer provided at a lowermost level of the wiring substrate and bonded to a top surface of the insulating substrate, and
an uppermost wiring layer provided at an uppermost level of the wiring substrate, a portion of the uppermost wiring layer being a semiconductor chip mounting wiring layer to which the semiconductor chip is bonded; and
a metal inlay embedded in the wiring substrate between the semiconductor chip and the insulting substrate, the metal inlay being electrically connected to the semiconductor chip.

2. The semiconductor module according to claim 1, wherein:
the plurality of wiring layers further includes a plurality of inner wiring layers provided between the lowermost wiring layer and the uppermost wiring layer, and
the plurality of inner wiring layers is electrically connected to each other through first conductive vias, and is electrically connected to the uppermost wiring layer through second conductive vias.

3. The semiconductor module according to claim 2, wherein:
the lowermost wiring layer is formed of a plurality of portions, one portion being a first lowermost wiring layer that is electrically connected to the plurality of inner wiring layers through third conductive vias and that has a back surface bonded to the top surface of the insulating substrate.

4. The semiconductor module according to claim 1, wherein the metal inlay has:
a top surface thereof bonded to a first electrode of the semiconductor chip,
a bottom surface thereof bonded to the top surface of the insulating substrate, and
a side surface, an uppermost portion thereof being in contact with the semiconductor chip mounting wiring layer, and a lowermost portion thereof being is in contact with the lowermost wiring layer.

5. The semiconductor module according to claim 1, wherein:
the uppermost wiring layer is formed of a plurality of portions, one portion being a circuit element mounting uppermost wiring layer configured to have a circuit element for controlling the semiconductor chip mounted thereon.

6. The semiconductor module according to claim 1, wherein:
the semiconductor chip has a first electrode, a second electrode and a control electrode,
the uppermost wiring layer is formed of a plurality of portions, which includes:
a first uppermost wiring layer bonded to the control electrode of the semiconductor chip,
a second uppermost wiring layer connected to the second electrode of the semiconductor chip, and
a third uppermost wiring layer to which the second electrode of the semiconductor chip and an external output terminal are connected,
the control electrode of the semiconductor chip and the first uppermost wiring layer are electrically connected via a first wiring member,
the second electrode of the semiconductor chip and the second uppermost wiring layer are bonded via a second wiring member, and
the second electrode of the semiconductor chip and the third uppermost wiring layer are bonded via a third wiring member.

7. The semiconductor module according to claim 6, wherein:
each of the first wiring member, the second wiring member, and the third wiring member is a bonding wire.

8. The semiconductor module according to claim 6, wherein:
the first wiring member is a first wire, the second wiring member is a second wire, and the third wiring member is a lead frame.

9. The semiconductor module according to claim 6, wherein:
each of the first wiring member, the second wiring member, and the third wiring member is a flexible substrate.

10. The semiconductor module according to claim 1, wherein:
the insulating layer of the wiring substrate is formed of a resin insulating layer,
the plurality of wiring layers and the resin insulating layer are laminated to integrate the insulating substrate and the wiring substrate to thereby form a resin insulating substrate, and
the metal inlay is embedded in the resin insulating substrate.
